(19) United States
(12) Patent Application Publication
(10) Pub. No.: US 2021/0090845 A1
(43) Pub. Date: Mar. 25, 2021

(54) ELECTROSTATIC FILTER WITH SHAPED ELECTRODES

(71) Applicant: APPLIED Materials, Inc., Santa Clara, CA (US)

(72) Inventors: Robert C. Lindberg, Rockport, MA (US); Alexandre Likhanskii, Malden, MA (US); Wayne LeBlanc, Gloucester, MA (US); Frank Sinclair, Boston, MA (US); Svetlana Radovanov, Brookline, MA (US)

(73) Assignee: APPLIED Materials, Inc., Santa Clara, CA (US)

(21) Appl. No.: 16/575,969

(22) Filed: Sep. 19, 2019

(51) Int. Cl. H01J 37/12; H01J 37/147; H01J 37/24; H01J 37/317

(52) U.S. Cl. CPC H01J 37/12; H01J 37/1472; H01J 2237/121; H01J 37/3171; H01J 37/241

(57) ABSTRACT

Provided herein are approaches for controlling an ion beam using an electrostatic filter with curved electrodes. In some embodiments, a system may include an electrostatic filter receiving an ion beam, the filter including first and second electrodes disposed opposite sides of an ion beam line, each of the first and second electrodes having a central region between first and second ends, wherein a distance between a first outer surface of the first electrode and a second outer surface of the second electrode varies along an electrode length axis extending between the first and second ends. The system may further include a power supply in communication with the electrostatic filter, the power supply operable to supply a voltage and a current to the first and second electrodes, wherein the variable distance between the first and second outer surfaces causes the ion beam to converge or diverge.

### FIELD OF THE DISCLOSURE

The disclosure relates generally to techniques for manufacturing electronic devices, and more particularly, to techniques for controlling an ion beam using a electrostatic filter with shaped electrodes.

### BACKGROUND OF THE DISCLOSURE

Ion implantation is a process of introducing dopants or impurities into a substrate via bombardment. In semiconductor manufacturing, the dopants are introduced to alter electrical, optical, or mechanical properties. For example, dopants may be introduced into an intrinsic semiconductor substrate to alter the type and level of conductivity of the substrate. In manufacturing an integrated circuit (IC), a precise doping profile provides improved IC performance. To achieve a desired doping profile, one or more dopants may be implanted in the form of ions in various doses and various energy levels.

Ion implantation systems may comprise an ion source and a series of beam-line components. The ion source may comprise a chamber where desired ions are generated. The ion source may also comprise a power supply and an extraction electrode assembly disposed near the chamber. The beam-line components may include, for example, a mass analyzer, one or more analyzing magnets, a first acceleration or deceleration stage, a collimator, and a second acceleration or deceleration stage. The analyzing magnets select desired ion species, filter out contaminant species and ions having undesirable energies, and adjust ion beam quality at a target wafer. Suitably shaped electrodes may modify the energy and the shape of an ion beam. Much like a series of optical lenses for manipulating a light beam, the beam-line components can filter, focus, accelerate, decelerate, and manipulate ions or an ion beam to have a desired species, shape, energy, and/or other quality. The ion beam passes through the beam-line components and may be directed toward a substrate mounted on a platen or clamp. The substrate may be moved in one or more dimensions (e.g., translate, rotate, and tilt) in the beam to achieve the desired process results.

Significant changes in ion energies taking place in the optical elements of the beamline components may have a substantial impact on a shape of the ion beam. For example, a deceleration lens may face challenges associated with control of deflection angle and beam focus, particularly as current increases in the ion implantation system. In some cases, a linear field across a ribbon shaped ion beam tends to diverge horizontally. One approach to mitigate beam divergence is to tune edge focus electrodes in an attempt to redirect outer beam rays. However, beam rays that are inboard of the edge focus electrodes cannot be adequately controlled.

### SUMMARY

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

In one embodiment, an ion implantation system may include an electrostatic filter receiving an ion beam, the electrostatic filter including a first electrode disposed along one side of an ion beam line and a second electrode disposed along a second side of the ion beam line, each of the first and second electrodes having a central region between first and second ends, wherein a distance between a first outer surface of the first electrode and a second outer surface of the second electrode varies along an electrode length axis extending between the first and second ends, or along a second axis extending along the ion beam line. The ion implantation system may further include a power supply in communication with the electrostatic filter, the power supply operable to supply a voltage and a current to the first and second electrodes, wherein the variable distance between the first and second outer surfaces causes the ion beam to converge or diverge in response to the voltage and the current.

In another embodiment, an electrostatic lens may include a first electrode disposed along one side of an ion beam line, and a second electrode disposed along a second side of the ion beam line, each of the first and second electrodes having a central region between first and second ends, wherein a distance between a first outer surface of the first electrode and a second outer surface of the second electrode varies along an electrode length axis extending between the first and second ends, or along a second axis extending along the ion beam line, and wherein a shape of the first and second outer surfaces causes the ion beam to converge or diverge in response to a voltage and a current supplied to the first or second electrodes.

In yet another embodiment, a method may include receiving an ion beam at an electrostatic filter, the electrostatic filter comprising a first plurality of electrodes disposed along a first side of an ion beam line and a second plurality of electrodes disposed along a second side of the ion beam line, each electrode of the first and second plurality of electrodes having a central region between first and second ends, wherein a distance between a first outer surface of a first suppression electrode of the first plurality of electrodes and a second outer surface of a second suppression electrode of the second plurality of electrodes varies along an electrode length axis extending between the first and second ends. The method may further include causing the ion beam to converge or diverge when passing through the first and second suppression electrodes by supplying a voltage and a current to the first and second suppression electrodes.

In still yet another embodiment, an electrode of an electrostatic filter may include a first end opposite a second end, and a central region between the first end and the second end, wherein a central diameter of the central region is different than a first end diameter of the first end and a second end diameter of the second end.

### BRIEF DESCRIPTION OF THE DRAWINGS

FIG. 1 is a schematic view illustrating an ion implantation system in accordance with embodiments of the present disclosure.

FIG. 2 a side cross-sectional view of an electrostatic filter of the ion implantation system shown in FIG. 1 in accordance with embodiments of the present disclosure.

FIG. 3 is a perspective view of a set of electrodes of the electrostatic filter of FIG. 2 in accordance with embodiments of the present disclosure.

FIG. 4 is a schematic view illustrating the electrostatic filter in accordance with embodiments of the present disclosure.

FIG. 5 is a perspective view of a set of electrodes of the electrostatic filter of FIG. 2 in accordance with embodiments of the present disclosure.

FIG. 6 a side cross-sectional view of a plurality of electrodes in accordance with embodiments of the present disclosure.

FIG. 7 is a flowchart illustrating an exemplary method according to the present disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

An ion implantation system, electrostatic lens, and method in accordance with the present disclosure will now be described more fully hereinafter with reference to the accompanying drawings, where embodiments of the disclosure are shown. The ion implantation system, electrostatic filter, and method may be embodied in many different forms and are not be construed as being limited to the embodiments set forth herein. Instead, these embodiments are provided so this disclosure will be thorough and complete, and will fully convey the scope of the system and method to those skilled in the art.

In view of the foregoing deficiencies identified with the prior art, provided herein are ion implantation systems, electrostatic lenses, and methods, which allow operation of a high-current implanter with improved performance. At high ion beam currents, there may be a problem of controlling horizontal beam divergence. To compensate for this, embodiments herein provide shaped electrodes to control beam divergence, while also improving beam current utilization, for example, when used with deflected, deflected deceleration, and/or other ribbon beam apparatuses.

Embodiments herein include an electrostatic lens for a ribbon beam, which introduces an electrostatic quadrupole field to control beam divergence during deflection and deceleration. In one embodiment, ion beam divergence may be controlled by increasing the voltage on one or more electrodes of the lens. In another embodiment, beam input width may be changed while using a fixed electrode voltage. As the beam widens the quadrupole field is stronger, which provides more horizontal focus for high perveance beams. In both cases, the electrostatic lens of the present disclosure may take a substantially parallel input ribbon beam and produce a parallel output ribbon beam with improved x/x′ characteristics and uniformity J(x) over the region of interest.

As will be described herein, at least the following technical advantages are achieved by the embodiments of the present disclosure. Firstly, controlling ion beam divergence by increasing the electrode voltage causes the ion beam to be vertically focused, which can minimize over-scan and improve throughput. Secondly, as voltage is increased, the ion beam may converge or diverge horizontally to a desired beam angle spread, which both improves usable beam current on the wafer, and allows for higher productivity or lower source currents. Thirdly, by optimizing beam angle distribution for a fixed electrode voltage, a lower voltage may be used. Fourthly, by modulating parameters that control the ion beam input width, beam angles can be tuned from converging (i.e., wide beam), diverging (i.e., narrow beam), to a parallel beam. Furthermore, by modulating both the parameters that control the ion beam input width and the electrode voltage, beam height can be modulated while maintaining desired current and horizontal beam angle divergence. Fifthly, narrower ribbon beams may be transported in the beamline with less strike on horizontal surfaces, thus creating less particulate matter and leading to lower cost of ownership.

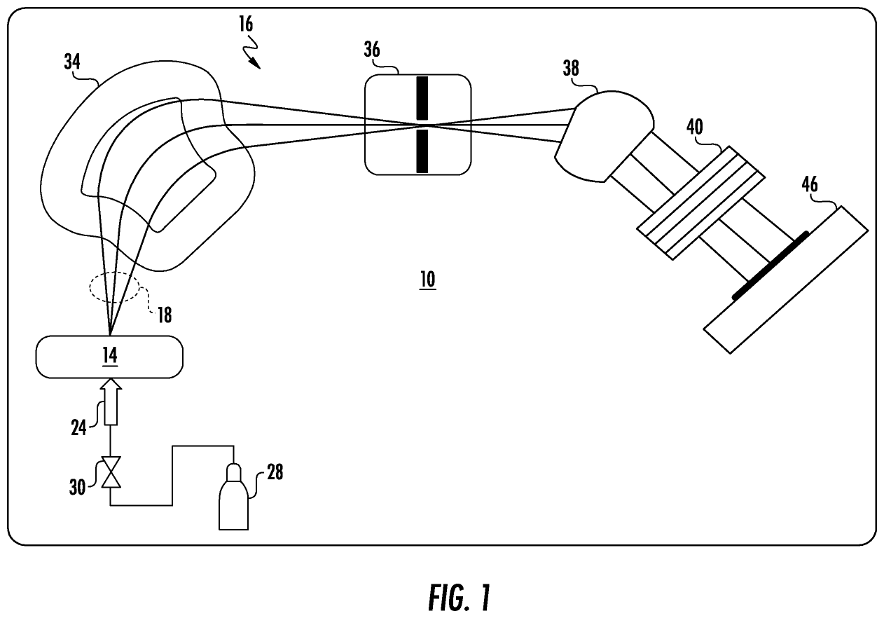

Referring now to FIG. 1, an exemplary system in accordance with the present disclosure is shown. The ion implantation system (hereinafter “system”) 10 represents a process chamber containing, among other components, an ion source 14 for producing an ion beam 18, an ion implanter, and a series of beam-line components 16. The ion source 14 may comprise a chamber for receiving a flow of gas 24 and generating ions therein. The ion source 14 may also comprise a power source and an extraction electrode assembly disposed near the chamber. The beam-line components 16 may include, for example, a mass analyzer 34, a first acceleration or deceleration stage 36, a collimator 38, and an electrostatic filter (EF) 40, which may also be referred to as an electrostatic lens herein. The EF 40 may correspond to a deflection and/or deceleration stage. Although not shown, the beam-line components 16 may further include a plasma flood gun (PFG) downstream of the EF 40.

In exemplary embodiments, the beam-line components 16 may filter, focus, accelerate, decelerate, and otherwise manipulate ions or the ion beam 18 to have a desired species, shape, energy, and other qualities. The ion beam 18 passing through the beam-line components 16 may be directed toward a substrate mounted on a platen or clamp within a process chamber 46. As appreciated, the substrate may be moved in one or more dimensions (e.g., translate, rotate, and tilt).

As shown, there may be one or more feed sources 28 operable with the chamber of the ion source 14. In some embodiments, material provided from the feed source 28 may include source material and/or additional material. The source material may contain dopant species introduced into the substrate in the form of ions. Meanwhile, the additional material may include diluent, introduced into the ion source chamber of the ion source 14 along with the source material to dilute the concentration of the source material in the chamber of the ion source 14. The additional material may also include a cleaning agent (e.g., an etchant gas) introduced into the chamber of the ion source 14 and transported within the system 10 to clean one or more of the beam-line components 16.

In various embodiments, different species may be used as the source and/or the additional material. Examples of the source and/or additional material may include atomic or molecular species containing boron (B), carbon (C), oxygen (O), germanium (Ge), phosphorus (P), arsenic (As), silicon (Si), helium (He), neon (Ne), argon (Ar), krypton (Kr), nitrogen (N), hydrogen (H), fluorine (F), chlorine (Cl), aluminum (Al), antimony (Sb), Indium (In), Carborane, and Naphthalene. Those of ordinary skill in the art will recognize the above listed species are non-limiting, and other atomic or molecular species may also be used. Depending on the application(s), the species may be used as the dopants or the additional material. In particular, one species used as the dopants in one application may be used as the additional material in another application, or vice-versa.

In exemplary embodiments, the source and/or additional material is provided into the ion source chamber of the ion source 14 in gaseous or vapor form. If the source and/or additional material is in non-gaseous or non-vapor form, a vaporizer (not shown) may be provided near the feed source 28 to convert the material into gaseous or vapor form. To control the amount and the rate the source and/or the additional material is provided into the system 10, a flowrate controller 30 may be provided.

The EF 40 may be configured to independently control deflection, deceleration, acceleration, and focus of the ion beam 18. In one embodiment, the EF 40 is a vertical electrostatic energy filter (VEEF). As will be described in greater detail below, the EF 40 may include an electrode configuration comprising a set of upper electrodes disposed above the ion beam 18 and a set of lower electrodes disposed below the ion beam 18. The set of upper electrodes and the set of lower electrodes may be stationary and have fixed positions. A difference in potentials between the set of upper electrodes and the set of lower electrodes may also be varied along the central ion beam trajectory to reflect an energy of the ion beam 18 at each point along the central ion beam trajectory for independently controlling deflection, deceleration, acceleration, and/or focus of the ion beam 18.

Although non-limiting, the ion source 14 may include a power generator, plasma exciter, plasma chamber, and the plasma itself. The plasma source may be an inductively-coupled plasma (ICP) source, toroidal coupled plasma source (TCP), capacitively coupled plasma (CCP) source, helicon source, electron cyclotron resonance (ECR) source, indirectly heated cathode (IHC) source, glow discharge source, electron beam generated ion source, or other plasma sources known to those skilled in the art.

The ion source 14 may generate the ion beam 18 for processing a substrate. In various embodiments, the ion beam (in cross-section) may have a targeted shape, such as a spot beam or ribbon beam, as known in the art. In the Cartesian coordinate system shown, the direction of propagation of the ion beam 18 may be represented as parallel to the Z-axis, while the actual trajectories of ions with the ion beam 18 may vary. In order to process the substrate, the ion beam 18 may be accelerated to acquire a target energy by establishing a voltage (potential) difference between the ion source 14 and the wafer.

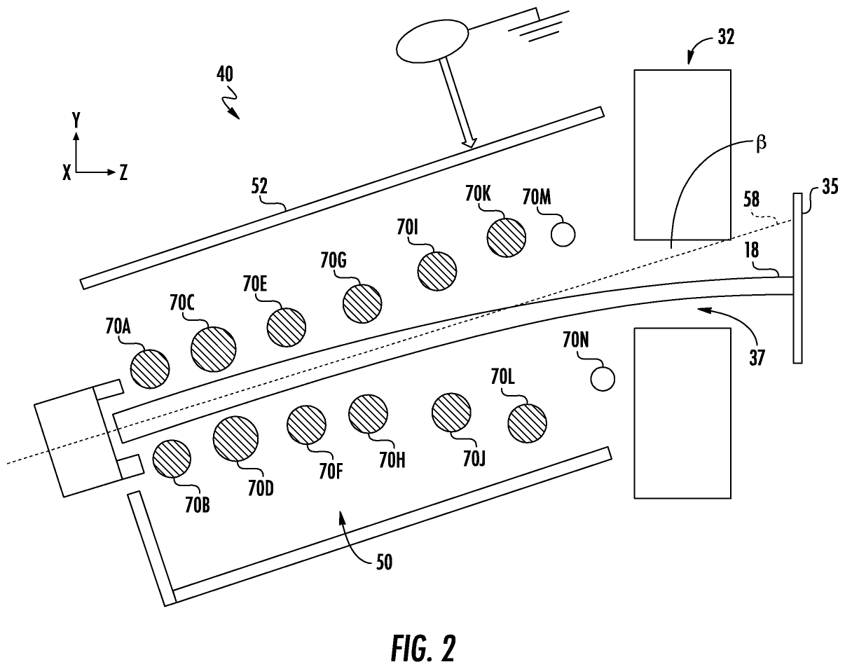

Referring now to FIG. 2, the EF 40 according to exemplary embodiments will be described in greater detail. As shown, the EF 40 includes an EF chamber 50 defined by a chamber housing 52. The EF 40 may further operate with one or more vacuum pumps (not shown) to adjust a pressure of the EF chamber 50. The EF 40 may be bordered along one end by a PFG 32, which has an opening 37 to permit the ion beam 18 to pass therethrough to the wafer 35. As shown, the PFG 32 is between the EF 40 and the wafer 35, and the PFG 32 and the wafer 35 are oriented at an angle β relative to an ion beam-line/trajectory 58. Although non-limiting, the angle β may be between 5-30°. Due to the arrangement of a plurality of electrodes 70A-70N within the EF chamber 50, and due to the orientation of the EF 40 relative to the PFG 32 and the wafer 35, the EF 40 may be considered “curved”.

In some embodiments, the electrodes 70A-70N may be graphite electrode rods disposed along the ion beam-line/trajectory 58. Although non-limiting, the plurality of electrodes 70A-70N may include a set (i.e., one or more) of entrance electrodes, a set of suppression electrodes, one or more focusing electrodes, and a set of exit electrodes. As shown, each set of electrode pairs provides a space/opening to allow the ion beam (e.g., a ribbon beam) 18 to pass therethrough.

In exemplary embodiments, the electrodes 70A-70N include pairs of conductive pieces electrically coupled to one another. Alternatively, the electrodes 70A-70N may be a series of unitary structures each including an aperture for the ion beam 18 to pass therethrough. In the embodiment shown, upper and lower portions of each electrode pair may have different potentials (e.g., in separate conductive pieces) in order to deflect, decelerate, accelerate, converge, or diverge the ion beam 18 passing therethrough.

In some embodiments, the ion beam 18 passing through the electrodes 70A-70N along the ion beam-line 58 may include boron or other elements. Electrostatic focusing of the ion beam may be achieved by using several thin electrodes (e.g., the suppression/focusing electrodes) to control grading of potential along the ion beam-line 58.

In some embodiments, a power supply 56 (e.g., a DC power supply) supplies a voltage and a current to the EF 40. The voltage/current may be supplied to electrodes 70A-70N to generate a plasma within the EF chamber 50. In various embodiments, the voltage and current provided by the power supply 56 may be constant or varied. The electrodes 70A-70N may be electrically driven in parallel (e.g., individually) or in series to enable uniform and/or independent operation of each of the electrodes 70A-70N. For example, the voltage for one or more suppression electrodes may be increased relative to the remaining electrodes of the EF 40 to manage convergence and divergence of the ion beam 18. In other embodiments, each of the electrodes 70A-70N has a different voltage.

As shown, the electrodes 70A-70N may be at different angular positions in the Z-direction. The effect is different field curvature between top and bottom electrodes, which can be compensated with different shaped profiles of one or more electrodes. The electric force necessary to deflect a beam particle in the x-direction at different positions in the z-direction can be expressed by the following equations:

$${qE}_{x} = \frac{2 ( {U}_{f} + {U}_{crt} ( {θ}_{z} ) )}{Δ z} tan ( α )$$

where U is beam energy, Δz=R·(θ_{gnd}−θ_{FOCUS}), α=beam divergence in X; and

$$\frac{dE}{Δ x} = - 2 k E$$

where k is a local field curvature.

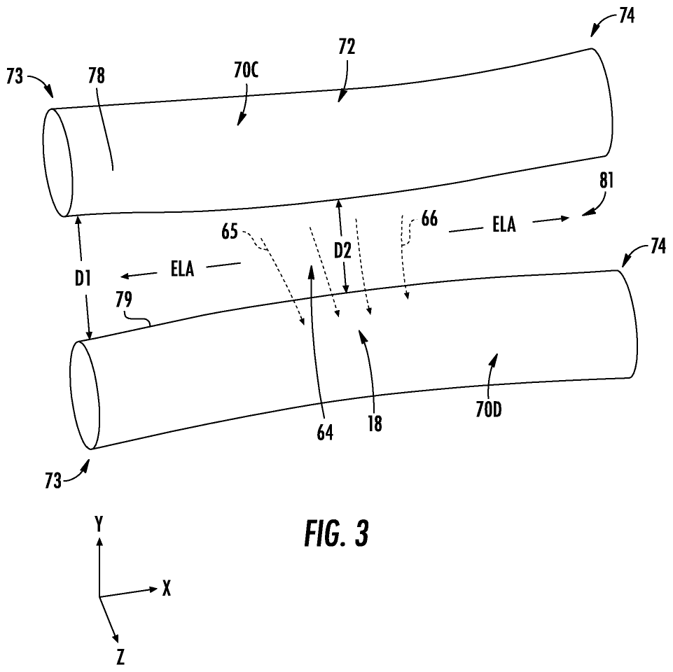

Turning now to FIG. 3, suppression electrodes 70C-70D will be described in greater detail. As shown, electrode 70C is disposed along a first side (e.g., above) the ion beam 18, while electrode 70D is disposed along a second side (e.g., below) the ion beam 18. Each of the electrodes 70C-70D may have a central region 72 between a first end 73 and a second end 74. A shown, a distance (e.g., along the y-axis) between a first outer surface 78 of electrode 70C and a second outer surface 79 of electrode 70D may vary along an electrode length axis ‘ELA’ (e.g., x-axis) extending between the first and second ends 73, 74. For example, a distance ‘D1’ between respective first and second outer surfaces 78, 79 of the first and second ends 73, 74 may be greater than a distance ‘D2’ at the central region 72. Although not shown, distance ‘D1’ between respective first and second outer surfaces 78, 79 may be different between the first and second ends 73, 74. In yet other embodiments, a diameter of either or both electrodes 70C-70D may vary between the first and second ends 73, 74. Stated differently, one end of the electrodes 70C-70D may diverge (e.g., widen) relative to the central region 72, while the other end of the electrodes 70C-D may converge (narrow) relative to the central region 72 to cause the ion beam 18 to both converge and diverge along the electrode length axis. Embodiments herein are not limited in this context.

As shown, the electrodes 70C-70D may be bent, curved, shaped, etc., such that the central regions 72 are closer to one another than at the first and second ends 73, 74. Although only electrodes 70C-70D are depicted as shaped in the present embodiment, it will be appreciated that other of electrodes 70A-70B and 70E-70N may be similarly shaped in alternative embodiments.

It will be appreciated that biasing the electrodes 70C-70D generates an electrostatic field between the electrodes 70C-70D. More specifically, the electrostatic field is a quadrupole field 81 formed in a gap between the electrodes 70C-70D. Although not shown, similar quadrupole fields may be formed between one or more pairs of the electrodes 70A-70N. By shaping the electrodes 70C-70D in the x and z directions, and applying a potential thereupon, the quadrupole field 81 may be modified, for example, in the x-y plane intersected by the ion beam 18. These changes in the quadrupole field 81 in turn cause ribbon beam divergence to change, affecting both a center 64 of the ion beam 18 and first and second beam edges 65, 66.

Furthermore, beam divergence control may be used to achieve an essentially parallel ion beam 18 along the x-direction and to cause the ion beam 18 to diverge or converge depending on the quadrupole field 81 strength defined by rod curvature, gap and voltage. This is beneficially achieved with minimal effects on the ion beam 18 in the y-direction.

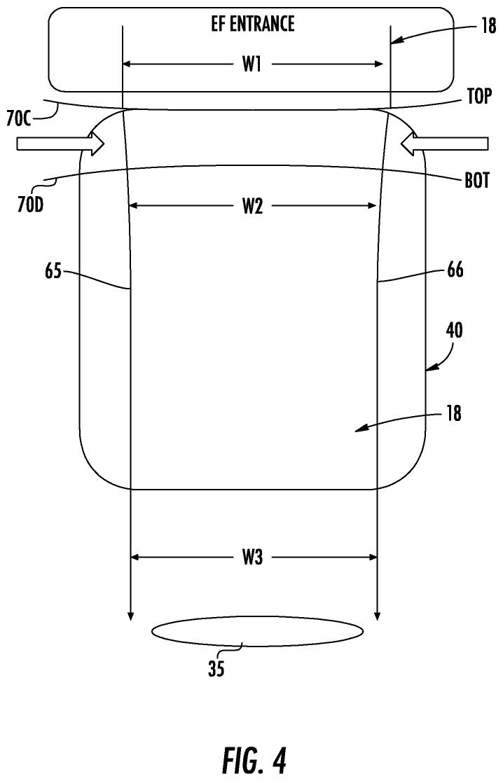

FIG. 4 demonstrates an example ion beam convergence using curved electrodes in the EF 40, such as electrodes 70C-70D described herein. As shown, the ion beam 18 is a ribbon beam having by a beam width defined by the first beam edge 65 and the second beam edge 66 on opposite sides thereof. The ion beam 18 has a width ‘W1’ as it enters the EF 40. As shown, the ion beam 18 is initially parallel, not having edge effects. As the ion beam 18 passes through the electrodes 70C-70D, the ion beam 18 converges or focuses to a second beam width, ‘W2’, wherein W1 is greater than W2. In other embodiments, the ion beam 18 may diverge as it passes through the EF 40. Due to the ion beam 18 entering the EF 40 parallel, the ion beam 18 may be tuned with suppression voltage and one or more focus electrodes. Advantageously, the ion beam 18 remains wide enough to tune uniformly and meet beam angle specifications. Finally, the ion beam 18 may exit the EF 40 and travel towards the wafer 35 at a third beam width, ‘W3’. In some embodiments, W1>W2>W3. As shown, the ion beam 18 exiting the EF 40 is generally parallel. Said differently, the first and second beam edges 65, 66 may extend parallel to one another as the ion beam 18 exits the EF 40.

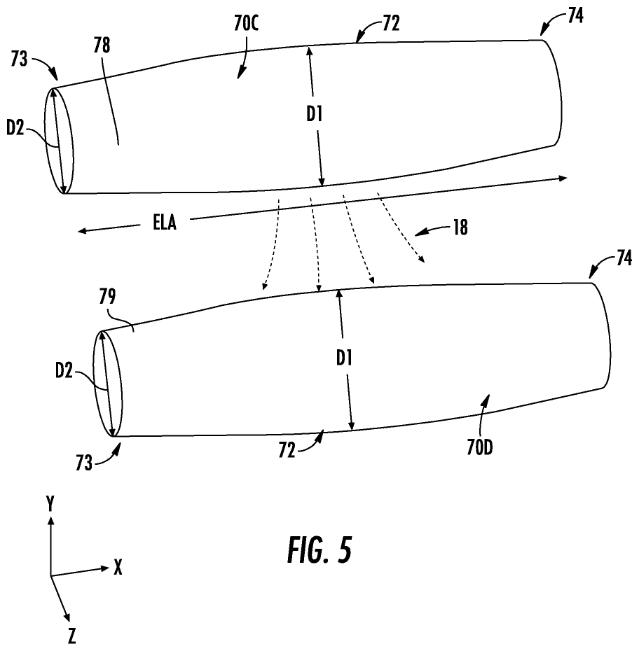

Turning now to FIG. 5, another example of suppression electrodes 70C-70D according to embodiments of the present disclosure will be described in greater detail. As shown, electrode 70C is disposed along a first side (e.g., above) the ion beam 18, while electrode 70D is disposed along a second side (e.g., below) the ion beam 18. Each of the electrodes 70C-70D may include the central region 72 between first and second ends 73, 74. A shown, a distance (e.g., along the y-axis) between the first outer surface 78 of electrode 70C and the second outer surface 79 of electrode 70D may vary along an electrode length axis ‘ELA’ (e.g., the x-axis) extending between the first and second ends 73, 74. More specifically, the electrodes 70C-70D may each widen towards the central region 72. Stated differently, the electrodes 70C-70D may be shaped such that a first diameter ‘D1’ in the central region 72 of the first and second electrodes 70C-70D may be greater than a second diameter ‘D2’ at the first and/or second ends 73, 74.

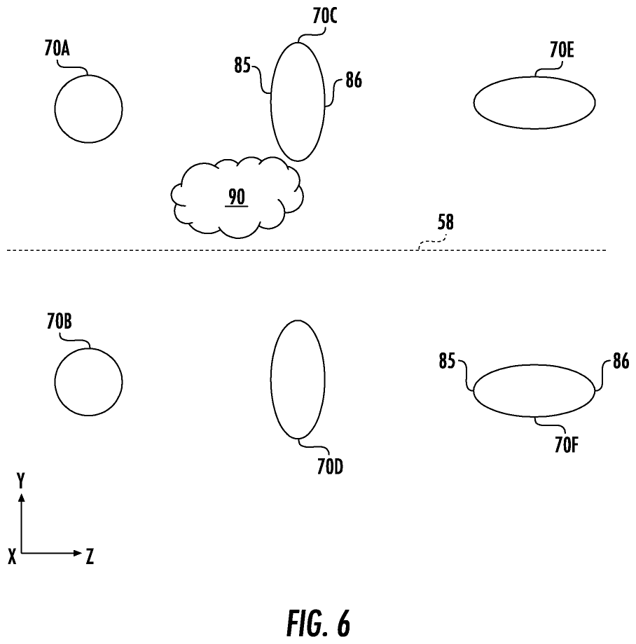

As better shown in FIG. 6, one or more of the plurality of electrodes 70A-70E may have a varied shape along the z-axis. For example, electrodes 70C-70F may generally have an oval cross section. Although non-limiting, electrodes 70C-70D may have an oblong shape in which a height along the y-axis is greater than a width along the z-axis. Electrodes 70E-70F may have an oblong shape in which the height along the y-axis is less than the width along the z-axis. Furthermore, although not demonstrated, one or more of electrodes 70A-70F may also have a varied shape along the x-axis and/or y-axis, for example, as described above.

In the embodiment shown, each of electrodes 70A-70F include an upstream side 85 and a downstream side 86 relative to a direction of travel (e.g., left to right) along the ion beam line 58. As shown, the distance between outer surfaces of electrodes 70A, 70C, and 70E and outer surface of electrodes 70B, 70D, and 70F, respectively, varies between the upstream side 85 and the downstream side 86. The shape(s) of the electrodes 70A-70F may be selected to change an electrostatic field 90 formed therebetween, along the ion beam line 58 in the z-direction.

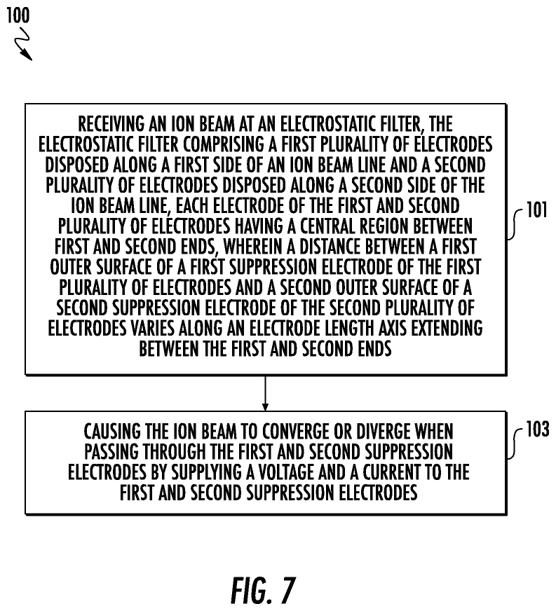

Referring now to FIG. 7, a flow diagram illustrating an exemplary method 100 in accordance with the present disclosure is shown. The method 100 may be described in conjunction with the representations shown in FIGS. 1-6.

At block 101, the method 100 may include receiving an ion beam at an electrostatic filter, the electrostatic filter comprising a first plurality of electrodes disposed along a first side of an ion beam line and a second plurality of electrodes disposed along a second side of the ion beam line, each electrode of the first and second plurality of electrodes having a central region between first and second ends, wherein a distance between a first outer surface of a first suppression electrode of the first plurality of electrodes and a second outer surface of a second suppression electrode of the second plurality of electrodes varies along an electrode length axis extending between the first and second ends.

At block 103, the method 100 may include causing the ion beam to converge or diverge when passing through the first and second suppression electrodes by supplying a voltage and a current to the first and second suppression electrodes. In some embodiments, the ion beam may converge or diverge by adjusting an initial ion beam width to achieve an intended beam angle spread and supplying a constant voltage to the first and second suppression electrodes after adjusting the initial ion beam width. In some embodiments, the ion beam may converge or diverge by increasing the voltage to the first and second suppression electrodes, for example, relative to the remaining electrodes of the first and second plurality of electrodes.

The foregoing discussion has been presented for purposes of illustration and description and is not intended to limit the disclosure to the form or forms disclosed herein. For example, various features of the disclosure may be grouped together in one or more aspects, embodiments, or configurations for the purpose of streamlining the disclosure. However, it should be understood that various features of the certain aspects, embodiments, or configurations of the disclosure may be combined in alternate aspects, embodiments, or configurations. Moreover, the following claims are hereby incorporated into this Detailed Description by this reference, with each claim standing on its own as a separate embodiment of the present disclosure.

As used herein, an element or step recited in the singular and proceeded with the word “a” or “an” should be understood as not excluding plural elements or steps, unless such exclusion is explicitly recited. Furthermore, references to “one embodiment” of the present disclosure are not intended to be interpreted as excluding the existence of additional embodiments that also incorporate the recited features.

The use of “including,” “comprising,” or “having” and variations thereof herein is meant to encompass the items listed thereafter and equivalents thereof as well as additional items. Accordingly, the terms “including,” “comprising,” or “having” and variations thereof are open-ended expressions and can be used interchangeably herein.

The phrases “at least one”, “one or more”, and “and/or”, as used herein, are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

All directional references (e.g., proximal, distal, upper, lower, upward, downward, left, right, lateral, longitudinal, front, back, top, bottom, above, below, vertical, horizontal, radial, axial, clockwise, and counterclockwise) are only used for identification purposes to aid the reader's understanding of the present disclosure, and do not create limitations, particularly as to the position, orientation, or use of this disclosure. Connection references (e.g., attached, coupled, connected, and joined) are to be construed broadly and may include intermediate members between a collection of elements and relative movement between elements unless otherwise indicated. As such, connection references do not necessarily infer that two elements are directly connected and in fixed relation to each other.

Furthermore, identification references (e.g., primary, secondary, first, second, third, fourth, etc.) are not intended to connote importance or priority, but are used to distinguish one feature from another. The drawings are for purposes of illustration only and the dimensions, positions, order and relative sizes reflected in the drawings attached hereto may vary.

Still furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision other modifications within the scope and spirit of the claims appended hereto.

1. An ion implantation system, comprising:
an electrostatic filter receiving an ion beam traveling along an ion beam line, wherein the ion beam is a ribbon ion beam defined by a main plane extending between first and second beam edges, the electrostatic filter including a first electrode disposed along one side of the ion beam line and a second electrode disposed along a second side of the ion beam line, each of the first and second electrodes having a central region between first and second ends, each of the first and second electrodes including an electrode length axis extending between the first and second ends, wherein the electrode length axis extends parallel to the main plane of the ribbon beam and orthogonal to the ion beam line, and wherein a first diameter in the central region of the first and second electrodes is greater than a second diameter at the first end and at the second end of the first and second electrodes; and
a power supply in communication with the electrostatic filter, the power supply operable to supply a voltage and a current to the first and second electrodes, wherein the variable distance between the first and second outer surfaces causes the ion beam to converge or diverge in response to the voltage and the current.

2. (canceled)

3. The ion implantation system of claim 1, wherein the first and second beam edges extend parallel to one another as the ion beam exits the electrostatic filter.

4. The ion implantation system of claim 1, wherein the first electrode and the second electrode include an upstream side and a downstream side relative to a direction of travel of the ion beam along the ion beam line, wherein a distance between a first outer surface of the first electrode and a second outer surface of the second electrode varies between the upstream side and the downstream side.

5. The ion implantation system of claim 1, wherein the first and second electrodes are suppression electrodes.

6. The ion implantation system of claim 1, wherein the first electrode or the second electrode has an oval cross-section.

7. The ion implantation system of claim 1, further comprising a first plurality of electrodes disposed along one side of the ion beam line and a second plurality of electrodes disposed along a second side of the ion beam line, wherein the voltage and the current are independently supplied to each of the first plurality of electrodes and the second plurality of electrodes.

8. The ion implantation system of claim 1, wherein the voltage and the current generate a quadrupole field between the first and second electrodes, and wherein a shape of the first and second outer surfaces modifies the quadrupole field in a plane intersected by the ion beam.

9. A lens, comprising:
a first electrode disposed along one side of an ion beam line; and
a second electrode disposed along a second side of the ion beam line, each of the first and second electrodes having a central region between first and second ends, each of the first and second electrodes including an electrode length axis extending between the first and second ends, wherein the electrode length axis extends parallel to a main plane of a ribbon ion beam traveling along the ion beam line and orthogonal to the ion beam line, and wherein a first diameter in the central region of the first and second electrodes is different greater than a second diameter at the first end and at the second end of the first and second electrodes.

10. (canceled)

11. The lens of claim 9, further comprising a chamber housing containing the first and second electrodes, wherein the ion beam is a ribbon beam defined by first and second beam edges, wherein the first and second beam edges extend parallel to one another as the ion beam exits the chamber housing.

12. The lens of claim 9, wherein the first electrode and the second electrode include an upstream side and a downstream side relative to a direction of travel of the ion beam along the ion beam line, wherein a distance between a first outer surface of the first electrode and a second outer surface of the second electrode varies between the upstream side and the downstream side.

13. The lens of claim 9, wherein the first and second electrodes are suppression electrodes.

14. The lens of claim 9, wherein the first electrode or the second electrode has an oval cross-section.

15. The lens of claim 9, further comprising a first plurality of electrodes disposed along one side of the ion beam line and a second plurality of electrodes disposed along a second side of the ion beam line, wherein the voltage and the current are independently supplied to each of the first plurality of electrodes and the second plurality of electrodes.

16. A method, comprising:
receiving a ribbon ion beam at an electrostatic filter, the electrostatic filter comprising a first plurality of electrodes disposed along a first side of an ion beam line and a second plurality of electrodes disposed along a second side of the ion beam line, each electrode of the first and second plurality of electrodes having a central region between first and second ends, each electrode of the first and second plurality of electrodes including an electrode length axis extending between the first and second ends, wherein the electrode length axis extends parallel to a main plane of the ribbon ion beam and orthogonal to the ion beam line, and wherein a first diameter in the central region of at least one electrode of the first plurality of electrodes and the second plurality of electrodes is greater than a second diameter at the first end and at the second end of the at least one electrode; and
causing the ion beam to converge or diverge when passing through the first and second suppression electrodes by supplying a voltage and a current to the first and second suppression electrodes.

17. The method of claim 16, further comprising causing the ion beam to converge or diverge by:
adjusting an initial ion beam width to achieve an intended beam angle spread; and
supplying a constant voltage to the first and second suppression electrodes after adjusting the initial ion beam width.

18. The method of claim 16, further comprising causing the ribbon ion beam to converge or diverge by increasing the voltage to the first and second suppression electrodes.

19. The method of claim 16, wherein the ribbon ion beam is defined by first and second beam edges, and wherein the first and second beam edges extend parallel to one another as the ion beam exits the electrostatic filter.

20. An electrode of an electrostatic filter, comprising:
a first end opposite a second end, wherein an electrode length axis extends between the first and second ends, and wherein the electrode length axis extends parallel to a main plane of a ribbon beam traveling past the first and second ends along an ion beam line; and
a central region between the first end and the second end, wherein a central diameter of the central region is greater than a first end diameter of the first end and a second end diameter of the second end.

21. (canceled)

22. The electrode of claim 20, wherein the first end diameter of the first end is different than the second end diameter of the second end.
